(19) United States
(12) Patent Application Publication
(10) Pub. No.: US 2026/0279933 A1
(43) Pub. Date: Sep. 17, 2026

(54) APPARATUS, BATTERY PACK, AND BATTERY-CELL DETERMINATION METHOD

(71) Applicant: SONY GROUP CORPORATION, TOKYO (JP)

(72) Inventors: GO TANAKA, TOKYO (JP); KUNIHARU SUZUKI, TOKYO (JP); KIMITAKA BENISE, TOKYO (JP); HIDETOSHI AKASAWA, TOKYO (JP); HIKARU FURUKAWA, TOKYO (JP); TATSUYA FURUYA, TOKYO (JP); POHSIANG CHEN, TOKYO (JP)

(21) Appl. No.: 19/471,834

(22) PCT Filed: Apr. 1, 2024
(86) PCT No.: PCT/JP2024/013397

§ 371 Date: Oct. 2, 2025

(30) Foreign Application Priority Data
Apr. 25, 2023 (JP) 2023-071667

(51) Int. Cl. H01M 10/42; G01R 19/165; G01R 31/388; G01R 31/389; G01R 31/396; H01M 4/02; H01M 4/133; H01M 10/44; H01M 10/48; H01M 50/105

(52) U.S. Cl. CPC H01M 10/4285; G01R 19/16576; G01R 31/388; G01R 31/389; G01R 31/396; H01M 4/133; H01M 10/425; H01M 10/44; H01M 10/484; H01M 50/105; H01M 2004/027; H01M 2010/4271

(57) ABSTRACT

An apparatus according to the present technology includes a specification section and a determination section. The specification section specifies a difference in voltage on an open circuit voltage (OCV) curve of a battery cell. The determination section determines whether the battery cell is authentic or non-authentic, on the basis of the difference in voltage.

### TECHNICAL FIELD

The present technology relates to an apparatus that includes a battery pack, the battery pack, and a battery-cell determination method.

### BACKGROUND ART

There are various apparatuses, such as electronic apparatuses and vehicles, that include removable battery packs. When a non-authentic battery pack is mounted on such an apparatus, this results in the cause of, for example, a failure or a quality accident. Thus, technologies used to determine whether a mounted battery pack is authentic or non-authentic have been developed. For example, Patent Literature 1 discloses a mobile terminal that includes a data communication terminal that performs data communication with a mounted battery pack, the mobile terminal determining whether the mounted battery pack is an authentic battery pack mounted on the basis of voltage of the data communication terminal.

### CITATION LIST

### Patent Literature

Patent Literature 1: Japanese Patent Application Laid-open No. 2009-118441

### DISCLOSURE OF INVENTION

### Technical Problem

However, when the method disclosed in Patent Literature 1 is applied, there is a need to provide a battery pack with a chip for data communication, and there is also a need to provide each of an apparatus and the battery pack with a terminal for data communication. This results in it costing a lot. Further, a battery pack typically includes battery cells and a control module on which a protection circuit for the battery cells is mounted, and it is difficult to determine that the battery pack in which non-authentic battery cells and an authentic control module are used in combination is non-authentic.

In view of the circumstances described above, it is an object of the present technology to provide an apparatus, a battery pack, and a battery-cell determination method that make it possible to accurately determine, at low costs, whether a battery cell is authentic.

### Solution to Problem

In order to achieve the object described above, an apparatus according to an embodiment of the present technology includes a specification section and a determination section.

The specification section specifies a difference in voltage on an open circuit voltage (OCV) curve of a battery cell.

The determination section determines whether the battery cell is authentic or non-authentic, on the basis of the difference in voltage.

The specification section may specify, as the difference in voltage, a difference between a voltage in a state of charge for determination on the OCV curve and a voltage in a state of charge for comparison on the OCV curve,
the state of charge for determination may be a state of charge in which a local reduction in voltage is caused on the OCV curve when the battery cell is authentic, and
the state of charge for comparison may be a state of charge in which the local reduction in voltage is not caused on the OCV curve when the battery cell is authentic.

When the difference in voltage is greater than or equal to a threshold, the determination section may determine that the battery cell is authentic, and
when the difference in voltage is less than the threshold, the determination section may determine that the battery cell is non-authentic.

The reduction in voltage may be a reduction in voltage that is caused due to impurities being added to at least one of a material for positive electrodes, a material for negative electrodes, or an electrolytic solution, the material for positive electrodes, material for negative electrodes, and electrolytic solution being included in the battery cell.

The negative electrode may be made of carbon, and
the impurities may be metallic silicon or a silicon compound that is added to the negative electrode.

The battery cell may be a cell of a lithium-ion battery.

The apparatus may further include
a measurement section that measures a value of a DC resistance of the battery cell by performing pulse charge on the battery cell; and
a derivation section that derives the OCV curve on the basis of the DC resistance.

In order to achieve the object described above, a battery pack according to an embodiment of the present technology includes a specification section and a determination section.

The specification section specifies a difference in voltage on an open circuit voltage (OCV) curve of a battery cell.

The determination section determines whether the battery cell is authentic or non-authentic, on the basis of the difference in voltage.

The battery pack may further include the battery cell, and a control module, and
the specification section and the determination section may be included in the control module.

In order to achieve the object described above, a battery-cell determination method according to an embodiment of the present technology includes
specifying a difference in voltage on an open circuit voltage (OCV) curve of a battery cell; and
determining whether the battery cell is authentic or non-authentic, on the basis of the difference in voltage.

### BRIEF DESCRIPTION OF DRAWINGS

FIG. 1 is a perspective view of an electronic apparatus according to embodiments of the present technology.

FIG. 2 is a plan view of a battery pack included in the electronic apparatus.

FIG. 3 is a perspective view of a battery cell included in the battery pack.

FIG. 4 is a perspective view of a control module included in the battery pack.

FIG. 5 illustrates an OCV curve of a typical battery cell.

FIG. 6 illustrates an OCV curve of a battery cell in which impurities have been added.

FIG. 7 illustrates an enlarged portion of FIG. 6.

FIG. 8 illustrates an OCV curve of a battery cell in which impurities have been added.

FIG. 9 is a block diagram illustrating a functional configuration of an information processing section included in the electronic apparatus.

FIG. 10 schematically illustrates an operation performed by a measurement section included in the information processing section.

FIG. 11 schematically illustrates a state of charge for determination and a state of charge for comparison that are specified by a specification section included in the information processing section.

FIG. 12 schematically illustrates a potential difference that is specified by the specification section included in the information processing section.

FIG. 13 is a block diagram illustrating a hardware configuration of the electronic apparatus.

### MODE(S) FOR CARRYING OUT THE INVENTION

An apparatus according to embodiments of the present technology is described. Examples of the apparatus according to the embodiments of the present technology include electronic apparatuses such as smartphones and notebook personal computers (PCs), vehicles such as electric automobiles and hybrid automobiles, and other apparatuses that include battery packs. An electronic apparatus is described below as an example.

### [Configuration of Electronic Apparatus]

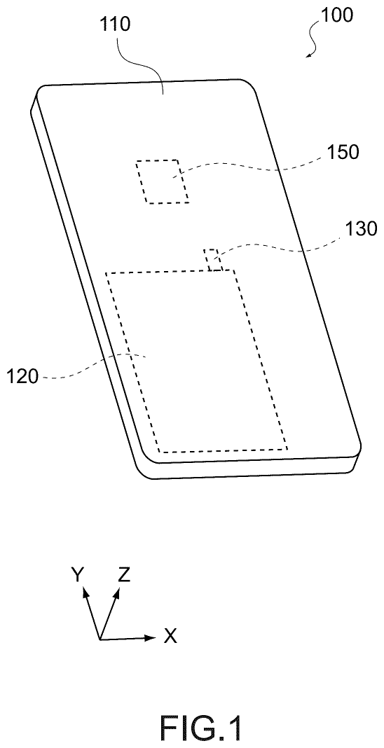

FIG. 1 is a perspective view of an electronic apparatus 100 according to the present embodiment. As illustrated in the figure, the electronic apparatus 100 includes an apparatus body 110 and a battery pack 120. The electronic apparatus 100 is, for example, a smartphone.

The apparatus body 110 is a portion obtained by excluding the battery pack 120 from the electronic apparatus 100. As illustrated in FIG. 1, the apparatus body 110 includes an information processing section 150. Further, the electronic apparatus 100 includes, for example, a display (not illustrated) and an operation button (not illustrated).

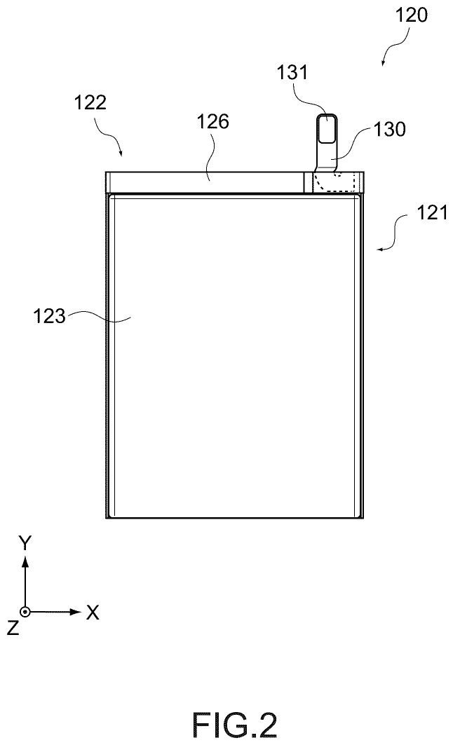

The battery pack 120 is mounted on the apparatus body 110, and serves as a power supply of the electronic apparatus 100. FIG. 2 is a plan view of the battery pack 120. As illustrated in the figure, the battery pack 120 includes a battery cell 121 and a control module 122.

The battery cell 121 is a cell of a secondary battery. The type of secondary battery is not particularly limited, and examples of the secondary battery may include a lithium-ion battery, a nickel-cadmium storage battery, a nickel-hydrogen battery, a sodium-sulfur battery, and a lead storage battery.

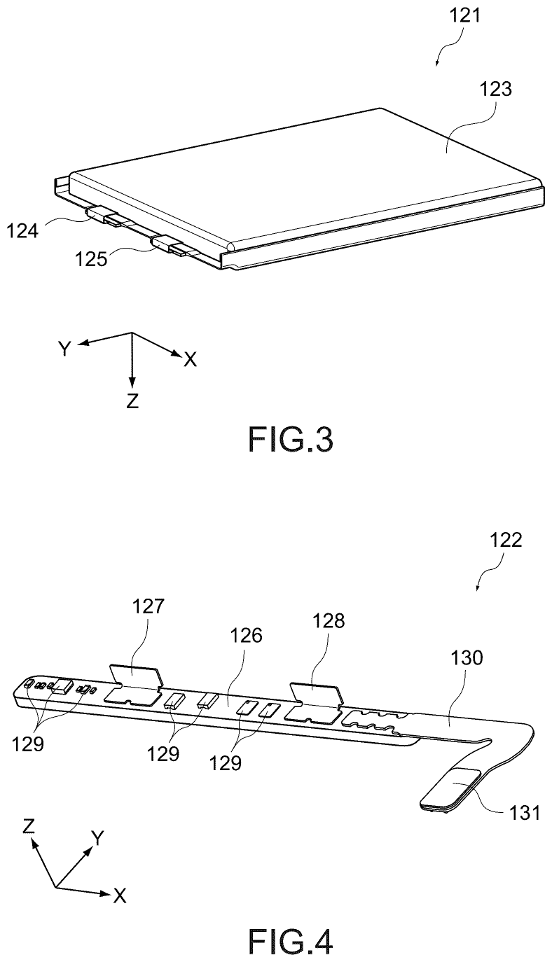

FIG. 3 is a perspective view of the battery cell 121. As illustrated in the figure, the battery cell 121 includes an exterior material 123, a positive-electrode terminal 124, and a negative-electrode terminal 125. The exterior material 123 accommodates therein a power storage element (not illustrated) and an electrolytic solution (not illustrated). The power storage element is formed by a material for positive electrodes and a material for negative electrodes being alternately stacked via a separator, and is immersed in the electrolytic solution. The positive-electrode terminal 124 is connected to the material for positive electrodes in the power storage element, and the negative-electrode terminal 125 is connected to the material for negative electrodes in the power storage element.

The control module 122 connects the battery cell 121 and the apparatus body 110, and controls the battery cell 121. FIG. 4 is a perspective view of the control module 122. As illustrated in the figure, the control module includes a support substrate 126, a positive-electrode terminal 127, a negative-electrode terminal 128, a protection circuit 129, a connection substrate 130, and a connector 131. The support substrate 126 is a substrate on which the components are mounted, and is, for example, a rigid substrate. The positive-electrode terminal 127 is a terminal that is connected to the positive-electrode terminal 124 of the battery cell 121, and the negative-electrode terminal 128 is a terminal that is connected to the negative-electrode terminal 125 of the battery cell 121.

For example, the protection circuit 129 is a circuit that protects the battery cell 121 from overcurrent, overvoltage, overcharge, and overdischarge, that protects the battery cell 121 thermally, that protects the battery cell 121 from a short, and that performs output monitoring on the battery cell 121. The protection circuit 129 includes electronic components such as an integrated circuit (IC). The connection substrate 130 is a substrate that connects the control module 122 and the apparatus body 110, and is, for example, a flexible substrate. Note that the connection substrate 130 illustrated in FIG. 2 is obtained by folding the connection substrate 130 illustrated in FIG. 4. The connector 131 is provided to the connection substrate 130 and connected to a connector of the apparatus body 110.

When the battery cell 121 and the control module 122 are connected to each other, the positive-electrode terminal 124 of the battery cell 121 is connected to a positive-electrode terminal of the apparatus body 110 through the positive-electrode terminal 127, the protection circuit 129, and the connector 131. Further, the negative-electrode terminal 125 of the battery cell 121 is connected to a negative-electrode terminal of the apparatus body 110 through the negative-electrode terminal 128, the protection circuit 129, and the connector 131.

The battery pack 120 has the configuration described above. Note that the configuration of the battery pack 120 is not limited to the configuration described above, and it is sufficient if the battery pack 120 includes at least the battery cell 121. Further, the number of battery cells 121 included in the battery pack 120 is not limited to one, and a plurality of battery cells 121 may be included in the battery pack 120.

### [Regarding OCV Curve of Battery Cell]

An open circuit voltage (OCV) curve of the battery cell 121 is described. The OCV curve is obtained by plotting an open circuit voltage (OCV) with respect to a state of charge (SOC), and is also called an SOC-OCV curve. The open circuit voltage is a voltage when a chemical reaction of a battery cell is in equilibrium. FIG. 5 illustrates an OCV curve of a typical cobalt-based lithium-ion battery. The cobalt-based lithium-ion battery is a battery in which lithium cobalt oxide (LiCOO₂) is used as a material for positive electrodes, carbon (C) such as graphite is used as a material for negative electrodes, and lithium salt containing liquid such as a lithium hexafluorophosphate (LiPF₆) solution is used as an electrolytic solution.

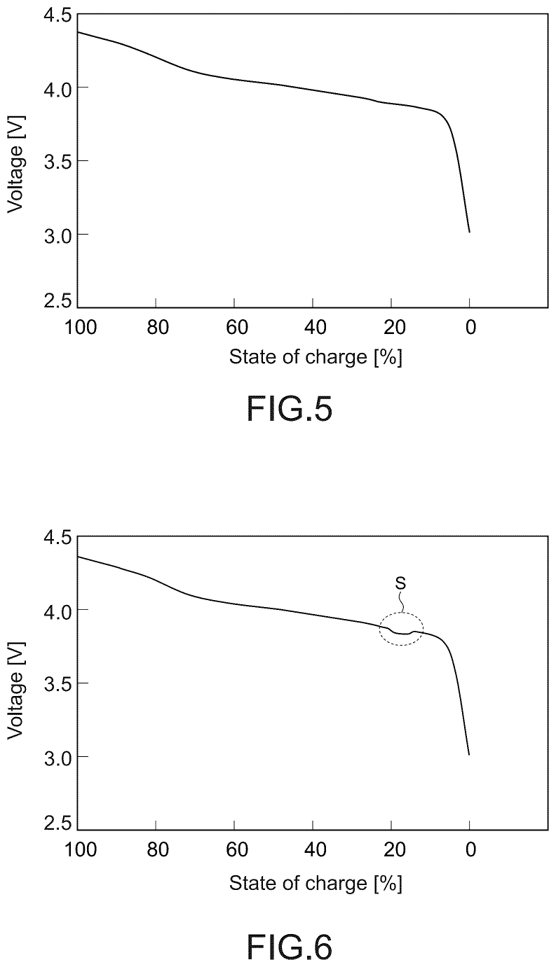

When impurities are added to the material for negative electrodes in the cobalt-based lithium-ion battery, the OCV curve varies. Metallic silicon (Si) or a silicon compound such as silicon monoxide (SiO) may be used as the impurities. Note that the theoretical specific capacity (4200 mAh/g) of silicon (Si) is about ten times greater than the theoretical specific capacity (372 mAh/g) of carbon (C), and addition of silicon (Si) to carbon (C) is under discussion in order to improve energy density of a battery cell. FIG. 6 illustrates an OCV curve of a cobalt-based lithium-ion battery in which silicon monoxide has been added to graphite used as a material for negative electrodes.

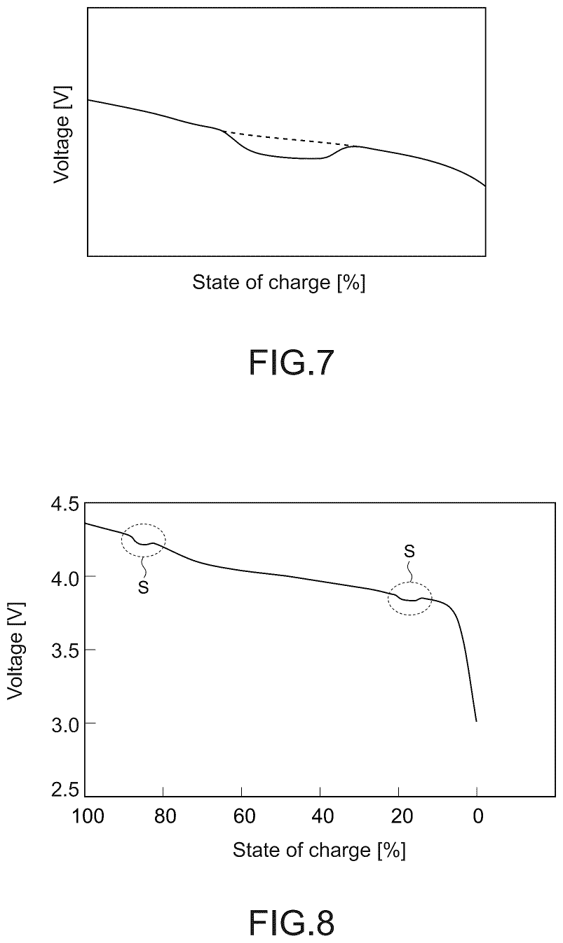

As indicated using a surrounded portion S in the figure, the addition of impurities results in a local reduction in voltage in a specific state of charge (around 10% to 20%). FIG. 7 illustrates an enlarged portion near the surrounded portion S of the OCV curve illustrated in FIG. 6. Further, the OCV curve (FIG. 5) of a cobalt-based lithium-ion battery in which impurities have not been added is indicated using a dashed line in the figure.

In the electronic apparatus 100 according to the present embodiment, the voltage reduction due to impurities is used to determine whether the battery cell 121 is authentic or non-authentic. Specifically, impurities have been added to an authentic battery cell, as described above, to cause a local reduction in voltage due to impurities. As described later, the battery cell 121 is determined to be authentic when the voltage reduction is detected in the apparatus body 110, and the battery cell 121 is determined to be non-authentic when the voltage reduction is not detected in the apparatus body 110.

Note that the cobalt-based lithium-ion battery in which silicon monoxide is added as impurities to graphite used as a material for negative electrodes has been described in the example above. However, the type of battery is not limited to a lithium-ion battery, and any of various secondary batteries may be used. Likewise, the impurities are not limited to silicon monoxide, and it is sufficient if the impurities are added to at least one of a material for negative electrodes, a material for positive electrodes, or an electrolytic solution in a battery cell to cause a local reduction in voltage. In the case of, for example, a cobalt-based lithium-ion battery, nickel (Ni) or manganese (Mn) may be added as impurities to a material for positive electrodes (lithium cobalt oxide). An amount of voltage reduction and a state of charge in which the voltage reduction is caused can be controlled by the type of impurities and an amount of addition.

Further, addition of multiple types of impurities in a battery cell also makes it possible to cause a voltage reduction in each of multiple portions on an OCV curve. FIG. 8 illustrates an example of an OCV curve on which a local reduction in voltage is caused in each of two portions indicated by the respective surrounded portions S. The local reduction in voltage may also be provided to each of three or more portions on the OCV curve.

### [Configuration of Information Processing Section]

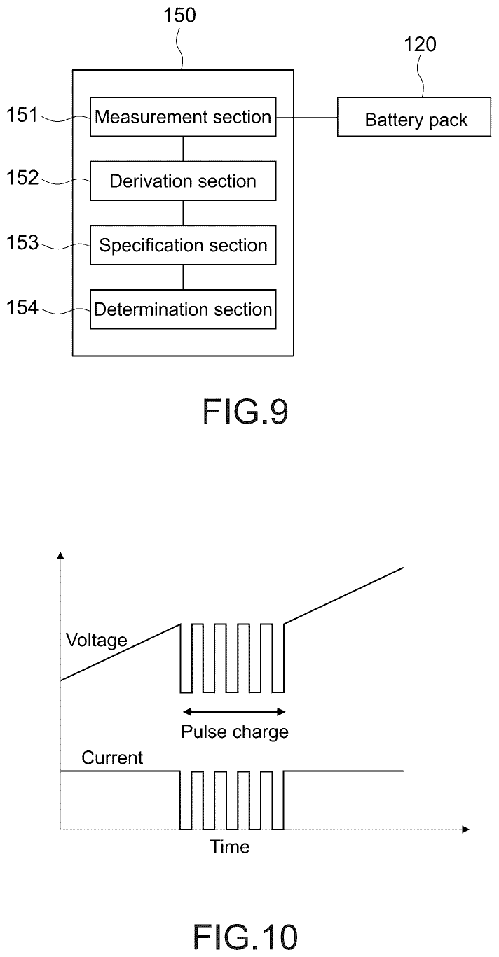

A configuration of the information processing section 150 is described. FIG. 9 schematically illustrates a functional configuration of the information processing section. As illustrated in the figure, the information processing section 150 includes a measurement section 151, a derivation section 152, a specification section 153, and a determination section 154. These structural elements correspond to a functional configuration implemented by software such as a program and hardware working cooperatively. Note that the information processing section 150 may be implemented by a central processing unit (CPU) of the electronic apparatus 100, or may be implemented by an information processing unit, such as an IC for battery control, that is different from the CPU.

The measurement section 151 measures a value of a direct current (DC) resistance (DCR) of the battery cell 121. FIG. 10 schematically illustrates an operation performed by the measurement section 151. As illustrated in the figure, the measurement section 151 performs pulse charge multiple times, and measures changes in voltage and current. Using Formula 1 indicated below, the measurement section 151 can calculate a DC resistance value (R) from a measurement value of measurement of voltage (V) and a measurement value of measurement of current (I)

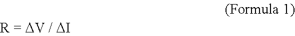

In this case, it is favorable that the measurement section 151 correct a DC resistance value according to an environment temperature upon charging and a level of a deterioration in the battery cell 121. The measurement section 151 supplies the value of the DC resistance of the battery cell 121 to the derivation section 152.

The derivation section 152 derives an OCV curve of the battery cell 121 on the basis of the DC resistance value supplied by the measurement section 151. In this case, an OCV curve on which a local reduction in voltage is caused, as illustrated FIG. 6, is derived when the battery cell 121 is authentic. On the other hand, an OCV curve on which a local reduction in voltage is not caused, as illustrated FIG. 5, is derived when the battery cell 121 is non-authentic. The derivation section 152 supplies the derived OCV curve to the specification section.

The specification section 153 specifies a “difference in voltage” on the OCV curve supplied by the derivation section 152. Specifically, the specification section 153 specifies, as the “difference in voltage”, a difference between a voltage in a “state of charge for determination” on the OCV curve and a voltage in a “state of charge for comparison” on the OCV curve.

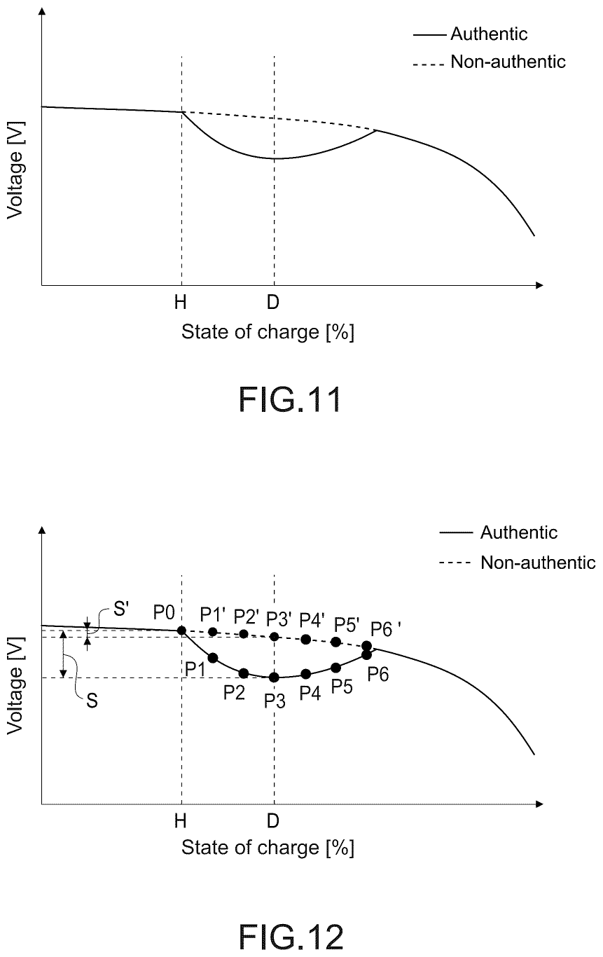

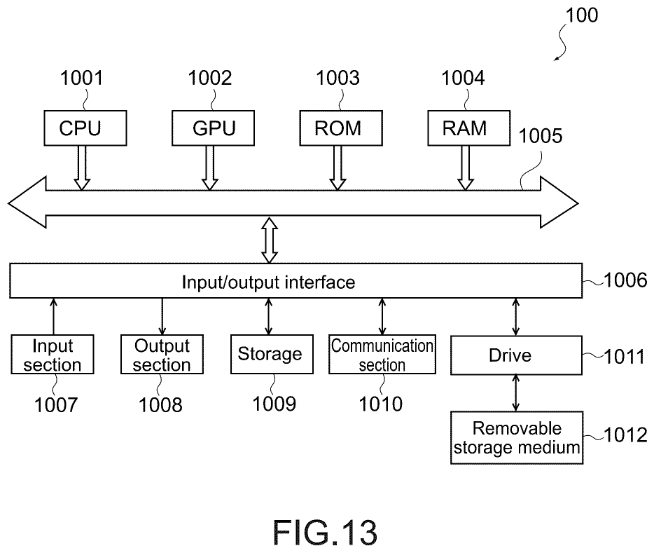

FIG. 11 is a graph in which a state of charge D for determination on an OCV curve and a state of charge H for comparison on the OCV curve are given. In the figure, a solid line indicates an OCV curve obtained when the battery cell 121 is authentic, and a dashed line indicates an OCV curve obtained when the battery cell 121 is non-authentic. As illustrated in the figure, the state of charge D for determination is a state of charge in which a local reduction in voltage is caused on an OCV curve when the battery cell 121 is authentic, and may be, for example, a state of charge in which a peak of the voltage reduction is observed.

As described above, when the battery cell 121 is authentic, impurities added to at least one of a negative electrode, a positive electrode, or an electrolytic solution cause a local reduction in voltage on an OCV curve. A manufacturer and a licensee of an authentic battery cell know, by the type of impurities and an amount of addition of the impurities, a state of charge in which a local reduction in voltage is caused, that is, the state of charge D for determination. Thus, the specification section 153 can specify voltage in the state of charge D for determination on an OCV curve.

Further, the state of charge H for comparison is a state of charge in which a local reduction in voltage is not caused on the OCV curve when the battery cell 121 is authentic, that is, the state of charge H for comparison is a state of charge in which an authentic battery cell and a non-authentic battery cell exhibit the same voltage on the OCV curve. The state of charge H for comparison may be, for example, a state of charge, from among the states of charge described above, that is greater than the state of charge D for determination and closest to the state of charge D for determination. The state of charge H for comparison is also known by the type of impurities and an amount of addition of the impurities. Thus, the specification section 153 can specify voltage in the state of charge H for comparison on an OCV curve.

The specification section 153 specifies, as the “difference in voltage”, a difference between a voltage in the state of charge D for determination on an OCV curve and a voltage in the state of charge H for comparison on the OCV curve. FIG. 12 schematically illustrates a method for specifying a difference in voltage, the specification being performed by the specification section 153, and illustrates an OCV curve that is similar to the OCV curve illustrated in FIG. 11. In the figure, a voltage P1 to a point P6 represent voltages for respective states of charge when the battery cell 121 is authentic, and a point P1′ to a point P6′ represent voltages for the respective states of charge when the battery cell 121 is non-authentic.

From among the voltages described above, the specification section 153 specifies a voltage in the state of charge D for determination and a voltage in the state of charge H for comparison. It is assumed that the voltage in the state of charge D for determination is the voltage P3 when the battery cell 121 is authentic, and that the voltage in the state of charge D for determination is the voltage P3′ when the battery cell 121 is non-authentic. It is assumed that the voltage in the state of charge H for comparison is the voltage P0 in each of the case in which the battery cell 121 is authentic and the case in which the battery cell 121 is non-authentic.

As illustrated in FIG. 12, the specification section 153 specifies, as a difference in voltage, a difference between the voltage P0 in the state of charge H for comparison and a voltage (P3 or P3′) in the state of charge D for determination. As illustrated in the figure, a difference S in voltage is obtained by “P0-P3” when the battery cell 121 is authentic, and is, for example, 20 mV. A difference S′ in voltage is obtained by “P0-P3′” when the battery cell 121 is non-authentic, and is, for example, 3 mV. Values obtained by “P0-P3” and “P0-P3′” vary depending on the type of battery cell 121, the type of impurities, and an amount of addition of the impurities. The specification section 153 supplies the specified difference in voltage to the determination section 154.

The determination section 154 determines whether the battery cell 121 is authentic or non-authentic, on the basis of the difference in voltage supplied by the specification section 153. Specifically, the determination section 154 holds a specified threshold. When the difference in voltage is greater than or equal to the threshold, the determination section 154 determines that the battery cell 121 is authentic, and, when the difference in voltage is less than the threshold, the determination section 154 determines that the battery cell 121 is non-authentic. The threshold may be, for example, 10 mV in the case described above.

As described above, the information processing section 150 can determine that the battery cell 121 exhibiting an OCV curve on which a local reduction in voltage is caused due addition of impurities is authentic, and can determine that the battery cell 121 exhibiting an OCV curve on which a local reduction in voltage is not caused is non-authentic. Using a method other than the method described above, the information processing section 150 may determine whether the battery cell 121 is authentic or non-authentic, on the basis of a difference in voltage on an OCV curve of the battery cell 121.

### [Effects Provided by Electronic Apparatus]

As described above, the electronic apparatus 100 can determine, from an OCV curve of the battery cell 121, whether the battery cell 121 is authentic or non-authentic. There is no need to provide the battery cell 121 and the apparatus body 110 with hardware, such as a chip for communication, that is used to determine whether the battery cell 121 is authentic. This makes it possible to accurately determine, at low costs, whether the battery cell 121 is authentic or non-authentic.

Further, the determination is performed using a change in characteristics of the battery cell 121 itself that is caused due to addition of impurities. Thus, the battery cell 121 can be determined to be non-authentic when the battery pack 120 formed by a non-authentic battery cell 121 and an authentic control module 122 being used in combination is mounted on the apparatus body 110.

### [Regarding Determination Performed by Control Module]

The example in which the information processing section 150 is included in the apparatus body 110 has been described above. However, the information processing section 150 may be included in the control module 122 (refer to FIG. 4) without being included in the apparatus body 110. In this case, when the control module 122 is connected to the battery cell 121, the control module 122 can determine whether the battery cell 121 to which the control module 122 is connected is authentic or non-authentic.

### [Another Configuration of Battery Pack]

The example in which the battery pack 120 includes one battery cell 121 and one control module 122 has been described above. However, the battery pack 120 may include a plurality of battery cells 121 and one control module 122. In this case, when OCV curves of the plurality of battery cells 121 are mixed and when only a portion of the plurality of battery cells 121 are non-authentic, it will be difficult to determine whether a non-authentic battery cell 121 is included. In this case, the battery cells 121 are separated from each other using, for example, switches in order not to mix the OCV curves of the respective battery cells 121. This makes it possible to determine each battery cell 121.

### [Hardware Configuration]

A hardware configuration of the electronic apparatus 100 that makes it possible to implement a functional configuration of the information processing section 150 is described. FIG. 12 schematically illustrates the hardware configuration.

As illustrated in the figure, the electronic apparatus 100 includes a central processing unit (CPU) 1001 and a graphics processing unit (GPU) 1002. An input/output interface 1006 is connected to the CPU 1001 and the GPU 1002 via a bus 1005. A read only memory (ROM) 1003 and a random access memory (RAM) 1004 are connected to the bus 1005.

An input section 1007, an output section 1008, a storage 1009, and a communication section 1010 are connected to the input/output interface 1006. The input section 1007 includes input devices such as a keyboard and a mouse that are used by a user to input an operation command. The output section 1008 outputs a processing operation screen and an image of a processing result to a display device. The storage 1009 includes, for example, a hard disk drive that stores therein a program and various data. The communication section 1010 includes, for example, a local area network (LAN) adapter, and performs communication processing through a network as represented by the Internet. Further, a drive 1011 is connected to the input/output interface 1006. The drive 1011 reads data from and writes data into a removable storage medium 1012 such as a magnetic disk, an optical disk, a magneto-optical disk, or a semiconductor memory.

The CPU 1001 performs various processes in accordance with a program stored in the ROM 1003, or in accordance with a program that is read from the removable storage medium 1012 such as a magnetic disk, an optical disk, a magneto-optical disk, or a semiconductor memory to be installed on the storage 1009, and is loaded into the RAM 1004 from the storage 1009. Data necessary for the CPU 1001 to perform various processes is also stored in the RAM 1004 properly. The GPU 1002 performs calculation processing necessary to draw an image under the control of the CPU 1001.

In the electronic apparatus 100 having the configuration described above, the series of processes described above is performed by the CPU 1001 loading, for example, a program stored in the storage 1009 into the RAM 1004 and executing the program via the input/output interface 1006 and the bus 1005.

For example, the program executed by the electronic apparatus 100 can be provided by being recorded in the removable storage medium 1012 serving as, for example, a package medium. Further, the program can be provided via a wired or wireless transmission medium such as a local area network, the Internet, or digital satellite broadcasting.

In the electronic apparatus 100, the program can be installed on the storage 1009 via the input/output interface 1006 by the removable storage medium 1012 being mounted on the drive 1011. Further, the program can be received by the communication section 1010 via the wired or wireless transmission medium to be installed on the storage 1009. Moreover, the program can be installed in advance on the ROM 1003 or the storage 1009.

Note that the program executed by the electronic apparatus 100 may be a program in which processes are chronologically performed in the order of the description in the present disclosure, or may be a program in which processes are performed in parallel or a process is performed at a necessary timing such as a timing of calling. Further, all of the hardware configuration of the electronic apparatus 100 does not have to be included in a single apparatus, and the electronic apparatus 100 may include a plurality of apparatuses. Further, a portion of or all of the hardware configuration of the electronic apparatus 100 may be included in a plurality of apparatuses connected to each other via a network.

### [Regarding Present Disclosure]

The effects described in the present disclosure are not limitative but are merely illustrative, and other effects may be provided. The above-described description of the plurality of effects does not necessarily mean that the plurality of effects is provided at the same time. The above-described description means that at least one of the effects described above is provided depending on, for example, a condition. There is a possibility that an effect that is not described in the present disclosure will be provided. Further, at least two of the features described in the present disclosure can also be used in combination.

Note that the present technology may also take the following configurations.

(1) An apparatus, including:
a specification section that specifies a difference in voltage on an open circuit voltage (OCV) curve of a battery cell; and
a determination section that determines whether the battery cell is authentic or non-authentic, on the basis of the difference in voltage.

(2) The apparatus according to (1), in which
the specification section specifies, as the difference in voltage, a difference between a voltage in a state of charge for determination on the OCV curve and a voltage in a state of charge for comparison on the OCV curve,
the state of charge for determination is a state of charge in which a local reduction in voltage is caused on the OCV curve when the battery cell is authentic, and
the state of charge for comparison is a state of charge in which the local reduction in voltage is not caused on the OCV curve when the battery cell is authentic.

(3) The apparatus according to (1) or (2), in which
when the difference in voltage is greater than or equal to a threshold, the determination section determines that the battery cell is authentic, and
when the difference in voltage is less than the threshold, the determination section determines that the battery cell is non-authentic.

(4) The apparatus according to (2) or (3), in which
the reduction in voltage is a reduction in voltage that is caused due to impurities being added to at least one of a material for positive electrodes, a material for negative electrodes, or an electrolytic solution, the material for positive electrodes, material for negative electrodes, and electrolytic solution being included in the battery cell.

(5) The apparatus according to any one of (4), in which
the negative electrode is made of carbon, and
the impurities are metallic silicon or a silicon compound that is added to the negative electrode.

(6) The apparatus according to any one of (1) to (5), in which
the battery cell is a cell of a lithium-ion battery.

(7) The apparatus according to any one of (1) to (6), further including:
a measurement section that measures a value of a DC resistance of the battery cell by performing pulse charge on the battery cell; and
a derivation section that derives the OCV curve on the basis of the DC resistance.

(8) A battery pack, including:
a specification section that specifies a difference in voltage on an open circuit voltage (OCV) curve of a battery cell; and
a determination section that determines whether the battery cell is authentic or non-authentic, on the basis of the difference in voltage.

(9) The battery pack according to (8), further including:
the battery cell; and
a control module, in which
the specification section and the determination section are included in the control module.

(10) A battery-cell determination method, including:
specifying a difference in voltage on an open circuit voltage (OCV) curve of a battery cell; and
determining whether the battery cell is authentic or non-authentic, on the basis of the difference in voltage.

### REFERENCE SIGNS LIST

100 electronic apparatus
110 apparatus body
120 battery pack
121 battery cell
122 control module
123 exterior material
150 information processing section
151 measurement section
152 derivation section
153 specification section
154 determination section

1. An apparatus, comprising:
a specification section that specifies a difference in voltage on an open circuit voltage (OCV) curve of a battery cell; and
a determination section that determines whether the battery cell is authentic or non-authentic, on a basis of the difference in voltage.

2. The apparatus according to claim 1, wherein
the specification section specifies, as the difference in voltage, a difference between a voltage in a state of charge for determination on the OCV curve and a voltage in a state of charge for comparison on the OCV curve,
the state of charge for determination is a state of charge in which a local reduction in voltage is caused on the OCV curve when the battery cell is authentic, and
the state of charge for comparison is a state of charge in which the local reduction in voltage is not caused on the OCV curve when the battery cell is authentic.

3. The apparatus according to claim 2, wherein
when the difference in voltage is greater than or equal to a threshold, the determination section determines that the battery cell is authentic, and
when the difference in voltage is less than the threshold, the determination section determines that the battery cell is non-authentic.

4. The apparatus according to claim 3, wherein
the reduction in voltage is a reduction in voltage that is caused due to impurities being added to at least one of a material for positive electrodes, a material for negative electrodes, or an electrolytic solution, the material for positive electrodes, material for negative electrodes, and electrolytic solution being included in the battery cell.

5. The apparatus according to claim 4, wherein
the negative electrode is made of carbon, and
the impurities are metallic silicon or a silicon compound that is added to the negative electrode.

6. The apparatus according to claim 5, wherein
the battery cell is a cell of a lithium-ion battery.

7. The apparatus according to claim 1, further comprising:
a measurement section that measures a value of a DC resistance of the battery cell by performing pulse charge on the battery cell; and
a derivation section that derives the OCV curve on a basis of the DC resistance.

8. A battery pack, comprising:
a specification section that specifies a difference in voltage on an open circuit voltage (OCV) curve of a battery cell; and
a determination section that determines whether the battery cell is authentic or non-authentic, on a basis of the difference in voltage.

9. The battery pack according to claim 8, further comprising:
the battery cell; and
a control module, wherein
the specification section and the determination section are included in the control module.

10. A battery-cell determination method, comprising:
specifying a difference in voltage on an open circuit voltage (OCV) curve of a battery cell; and
determining whether the battery cell is authentic or non-authentic, on a basis of the difference in voltage.
